(19) United States
(12) Patent Application Publication
(10) Pub. No.: US 2010/0172198 A1
(43) Pub. Date: Jul. 8, 2010

(54) DATA STORAGE ELEMENT SENSING DEVICE

(75) Inventors: Akhilesh GAUTAM, Uttar Pradesh (IN); Chirag GULATI, Madhya Pradesh (IN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Pvt. Ltd., Greater Noida (IN)

(21) Appl. No.: 12/648,731

(22) Filed: Dec. 29, 2009

(30) Foreign Application Priority Data
Dec. 30, 2008 (IN) 2971/DEL/2008

(51) Int. Cl. G11C 7/12; G11C 7/00; H01R 43/00; G11C 7/06

(52) U.S. Cl. 365/203; 365/205; 29/825; 365/207

(57) ABSTRACT

A sensing device for a data storage system may include a sensing circuit, a pull-down circuit, and a pull-up circuit. The sensing circuit may sense discharging of a desired bit line or a complementary bit line and may generate a desired output. The pull-down circuit may be coupled to the bit line and the complementary bit line for enhancing the discharging rate and may increase the sensing speed of the storage system. The pull-up circuit may control the discharging of an undesired bit line or complementary bit line.

### FIELD OF THE INVENTION

The present disclosure relates to data storage systems and more specifically to the sensing device used for sensing the stored data.

### BACKGROUND OF THE INVENTION

A static random access memory (SRAM) is a semiconductor memory. The word “static” indicates that a memory retains stored contents as long as power remains applied. The term random access depicts that locations in the memory can be written to or read from in any order, regardless of the memory location that was last accessed.

A conventional SRAM uses balanced differential sense amplifiers to sense the stored data in a selected memory cell. The balanced sense amplifier senses and amplifies the small differential voltage (V_{diff}) between a bitline (BL) and a complementary bitline (BLB) to give a single output as “Read 0” or “Read 1”. The sense amplifier turns ON when sufficient V_{diff} plus some margin defined by the design margin appears across its inputs.

The sense amplifier is enabled by a “Sense Enable” signal (SAEN). The design of the SRAM is such that the SAEN enables the sense amplifier only when the desired V_{diff} appears. To ensure reduced timing skew it may be desirable to provide dummy path circuitry to track the actual physical path delay. This extra circuitry together with a sense amplifier with adequate gain consumes approximately 40% extra area and approximately 30% more dynamic power. The timing of the SAN may be critical as it affects the robustness of the read operation as well as the performance of SRAM.

FIG. 1 illustrates an alternative approach using a conventional inverter based sensing device in an SRAM designed for small capacity compilers. The inverter based data sensing device (known as an inverter sensing device) includes an inverter for sensing the voltage level when either a “bit” or “bitbar” (Read 0/1) line reaches the threshold voltage level (VDD/2) of the inverter. The inverter sensing device has the advantage of reduced area and dynamic power at the expense of speed. The “bit” or “bitbar” line discharges by a memory cell current (ION) up to the threshold voltage level (VDD/2). The inverter sensing device is generally always ON and switches when bitline BL discharges to 50% of VDD. This architecture takes approximately 40% less area, approximately 30% less dynamic power and leakage with respect to SRAMs using sense amplifiers. However, the speed of the memory is reduced by approximately 70% since bitline sensing happens after 50% of BL discharge.

### BRIEF DESCRIPTION OF THE DRAWINGS

The aforementioned aspects and other features of the present disclosure will be explained in the following description, taken in conjunction with the accompanying drawings, wherein:

FIG. 1 illustrates a conventional inverter sensing device used in SRAM.

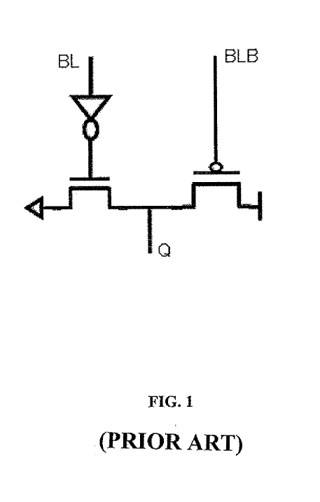

FIG. 2 illustrates a block diagram of a storage system according to the present disclosure.

FIG. 3 illustrates a block diagram of a sensing device according to the present disclosure.

FIG. 4 illustrates a circuit diagram of a sensing device according to the present disclosure.

FIG. 5 illustrates a flow diagram of a method for sensing data in a data storage system according to an embodiment of the present disclosure.

### DETAILED DESCRIPTION OF THE PREFERRED EMBODIMENTS

The embodiments of the present disclosure are described in detail with reference to the accompanying drawings. However, the present disclosure is not limited to these embodiments which are only provided to explain more clearly the present disclosure to the ordinarily skilled in the art of the present disclosure. In the accompanying drawings, like reference numerals are used to indicate like components.

The present disclosure teaches an inverter based sensing device used in data storage systems. The sensing device may enhance the memory speed and may consume smaller area and dynamic power. The sensing device may include an inverter sensing block, a pull-down block, and a pull-up block. The inverter sensing block may sense the discharging of a desired bit line (BL or BLB). The pull-down block may enhance the discharging rate of the desired bit line (BL or BLB) for increasing the sensing speed of the storage system. The pull-up block may control the discharging of the complementary bit line (BL or BLB).

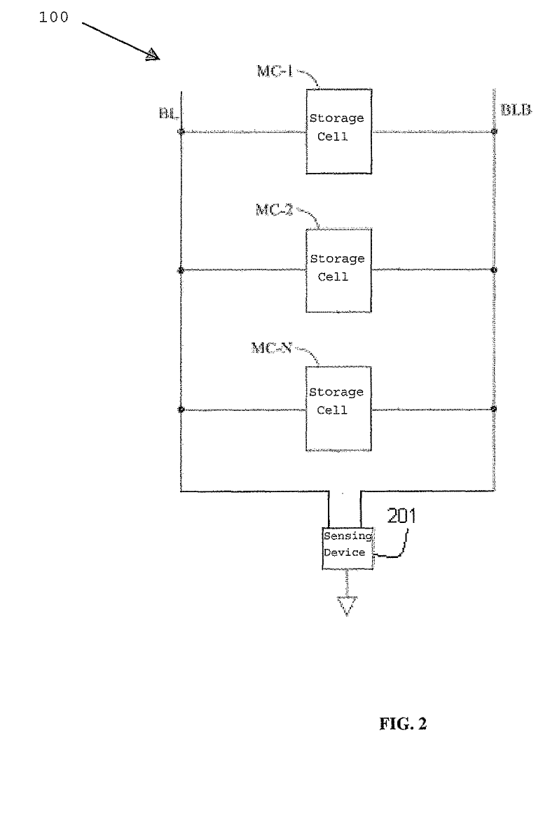

FIG. 2 illustrates a block diagram of a data storage system 100 according to an embodiment of the present disclosure. The storage system 100 includes one or more storage cells (MC-1, MC-2 . . . MC-N) and a sensing device 201. The sensing device 201 is coupled to the one or more storage cells (MC-1, MC-2 . . . MC-N) through a bit line BL and a complementary bit line BLB to read the any one of the storage cells (MC-1, MC-2 . . . MC-N).

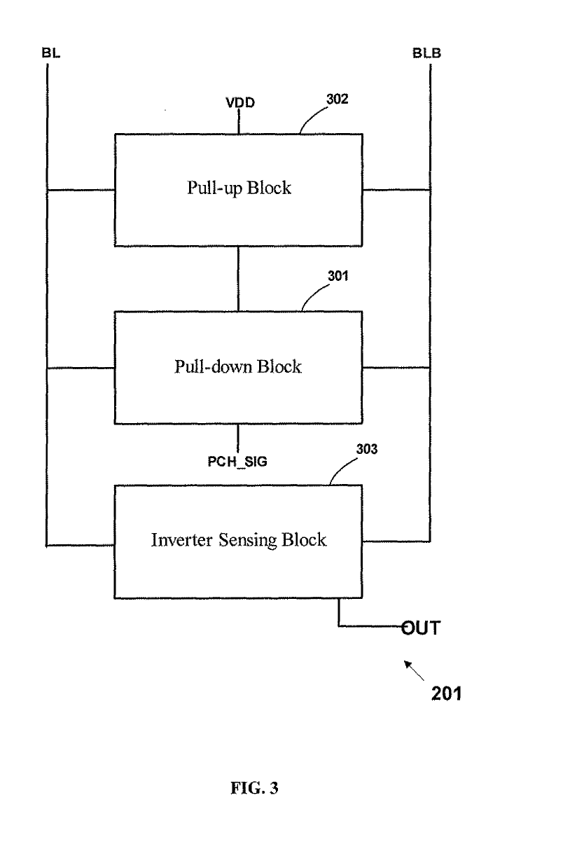

FIG. 3 illustrates a block diagram of a sensing device 201 according to the present disclosure. The sensing device 201 includes a pull-down block 301, a pull-up block 302, and an inverter sensing block 303. The pull-down block 301 is coupled to a bit line BL and its complementary bit line BLB. The pull-down block 301 discharges both bit lines (BL and BLB) of a selected data storage cell and thereby may enhance the discharging rate of the bit lines depending on READ-‘0’ or READ-‘1’ and increase the sensing speed of the storage system. The pull-up block 302 is coupled to the bit line BL and its complementary bit line BLB. The pull-up block 302 compensates for the discharging of the one of the bit lines which is at voltage level “1” and controls the discharging of bit line EL (or complementary bit line BLB) depending on READ-‘0’ or READ-‘1’. The inverter sensing block 303 is coupled to the bit line EL and its complementary bit line BLB for sensing the stored data.

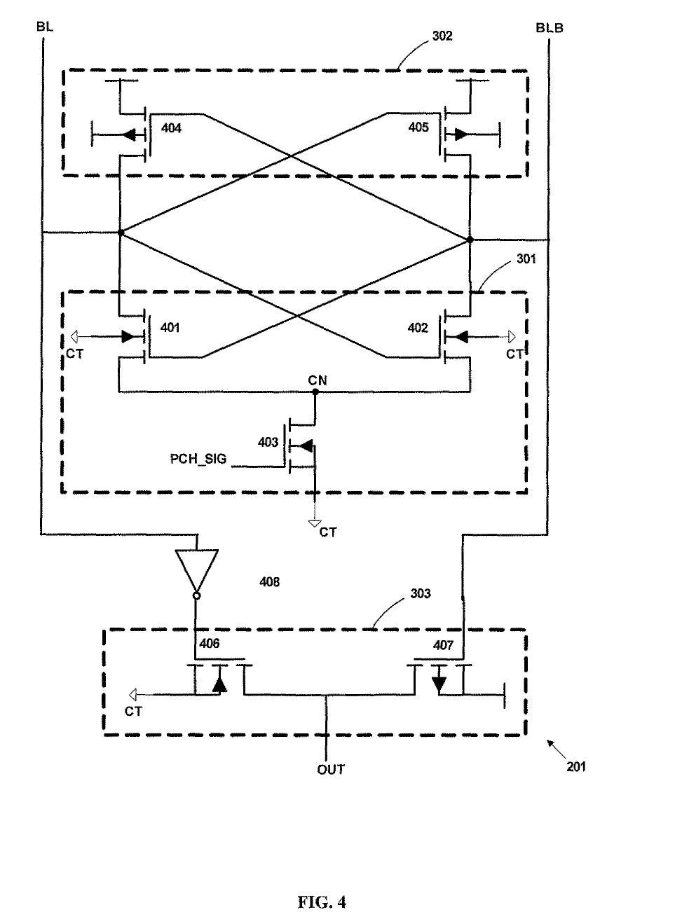

FIG. 4 illustrates a circuit diagram of a sensing device 201 according to an embodiment of the present disclosure. The pull down block 301 includes controlled switches 401, 402, and 403. First controlled switch 401 is coupled between a first bit line BL and a common node CN. The control terminal of controlled switch 401 is coupled to the second bit line BLB. Second controlled switch 402 is coupled between the second bit line BLB and the common node CN, and its control terminal is coupled to the first bit line BL. Third controlled switch 403 is coupled between the common node CN and a common terminal CT, and its control terminal is receiving a precharge signal PCH_SIG.

The pull-up block 302 includes controlled switches 404 and 405. Fourth controlled switch 404 is coupled between a supply voltage and the first bit line BL and has its control terminal coupled to the second bit line BLB. Fifth controlled switch 405 is coupled between the supply voltage and the second bit line BLB and has its control terminal coupled to the first bit line BL.

The inverter sensing block includes controlled switches 406 and 407. Sixth controlled switch 406 is coupled between the common terminal CT and an output node OUT and has its control terminal coupled to the first bit line BL through an inverter 408. Seventh controlled switch 407 is coupled between the supply voltage and the output node OUT and has its control terminal coupled to the second bit line BLB. In one embodiment, the controlled switch may be a transistor.

At the initial state of the sensing operation, bit line BL and complementary bit line BLB are at a voltage level VDD, which keeps transistors 406 and 407 OFF. BL or BLB then gets discharged depending on the READ-‘0’ or READ-‘1’, and starts using the ION current of the storage cell. In a READ-‘0’ case, BL discharges with the ION current of the storage cell. When the voltage level of BL reaches the threshold level of the inverter 408, it switches the inverter from ‘1’ to ‘1’ and makes transistor 406 ON. This makes output OUT ‘0’. At this time, line BLB is still at the supply voltage VDD and makes transistor 406 OFF. In a READ-‘1’ case, BLB discharges with the ION current of the storage cell. When BLB reaches the threshold level of transistor 407, the transistor 407 turns ON and provides output ‘1’ (i.e. OUT=‘1’). At this time, BL is still at VDD level and so transistor 406 is OFF.

Since the discharging of bit line BL (or BLB) up to the switching threshold level (i.e. VDD/2) takes significant time, the sensing speed of the storage system is reduced. The present disclosure includes pull-down block 301 for enhancing the discharging speed of the bit line BL (or BLB) up to its switching threshold level. Pull-down block 301 is controlled by the precharge signal PCH SIG for improving the discharging speed of BL/BLB. Therefore, the storage system takes less time to reach the VDD/2 switching level.

Consider the initial state of the sensing operation. Precharge signal PCH SIG goes high and switches transistor 403 ‘ON’. As both BL/BLB are at the supply level VDD (or precharge level), transistor 401 and 402 are ‘ON’. When transistor 403 turns ‘ON’, it creates a discharge path for both BL/BLB through transistors 401 and 403 (for BL) and through 402 and 403 (for BLB) respectively.

As the word line switches to a high state, the BL (or BLB) line discharges using the ION current of the storage cell depending on READ-‘0’ or READ-‘1’. For the READ-‘0’ case, the bit line BL (desired bit line) discharges using the ION current of the storage cell and the ISCHME current (ION˜=1.5-3 times of ISCHEME) of the pull-down block 301 through transistors 401 and 403, while the complementary bit line BLB may discharge with the ISCHME current of the pull-down block only through transistors 402 and 403.

For a READ-‘1’ case, the complementary bit line BLB (desired bit line) discharges with the ION current of the storage cell and the ISCHME current of the pull-down block 301 through transistors 402 and 403, while bit line BL discharges with the ISCHME current of the pull-down block 301 through transistors 401 and 403.

Since, the pull-down block 301 discharges with two currents ION and ISCHEME, the discharging rate of the desired bit line is enhanced. But, this may initiate the discharging of undesired bit line (or complementary bit line) with ISCHEME current. To compensate for this, a pull-up block 302, which controls the discharging of undesired bit line BL (or complementary bit line BLB) depending on READ-‘0’ or READ-‘1’, is used. The pull-up block may raise the voltage level of the undesired bit line BL (or BLB) to VDD or a precharge level.

Consider the initial state of the sensing operation during READ-‘0’ case. Bit line BL and the complementary bit line BLB are at VDD level, transistors 401 and 402 are ON, and transistors 403, 404, and 405 are OFF. As the precharge signal (PCH_SIG) and the word line switch to high level during READ-‘0’ case, bit line BL starts discharging. The BLB line also discharges, but at a slower rate. Transistors 401 and 403 are ON. The transistor 402 is weakly ‘ON’ and may tend to go ‘OFF’ (as BL goes to ‘0’). Transistor 405 is turning ON (as BL goes to ‘0’), and transistor 404 is OFF.

Finally during the READ-‘0’ case, the bit line BL achieves ‘0’ level, BLB achieves VDD level, the transistors 401, 403 and 405 switch to ‘ON’ state, and transistors 402 and 404 switch to ‘OFF’ state. Thus, the pull-up block 302 controls the discharging of undesired complementary bit line BLB for the READ-‘0’ case. Similarly for READ-1 case, the pull-up block controls the discharging of undesired bit line BL.

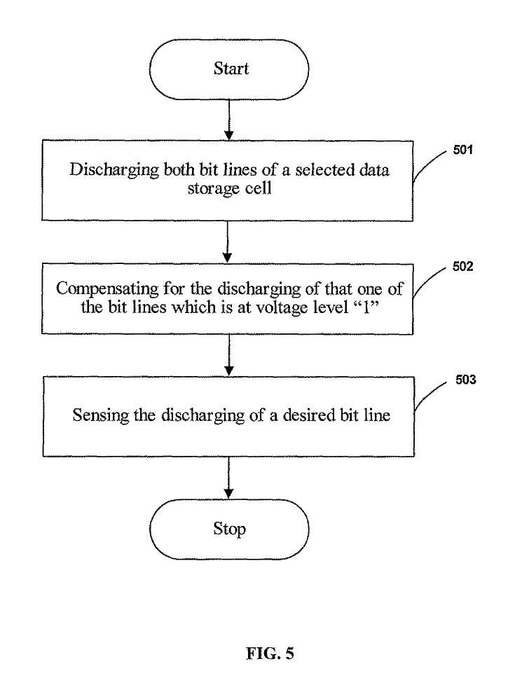

FIG. 5 illustrates a flow diagram of a method for sensing data in a data storage system according to an embodiment of the disclosure. Both the bit lines (BL and BLB) of a selected data storage cell are discharged 501. One bit line, which is at voltage level “1”, is pulled up for compensating its discharge 502. The discharging of a desired bit line is sensed to read the stored data 503.

The embodiments of the present disclosure, relating to a sensing device, may be used in various applications, such as in a memory device. The sensing device may enhance the reading speed of a storage system with reduced area and dynamic power.

Various embodiments of a sensing device and its implementation may be possible, such as a system including a device for sensing data in a dual bit line data storage system, a memory or a static random access memory (SRAM) including a device for sensing data, and a circuit for sensing data in a data storage system. Although the disclosure of the sensing device has been described in connection with various embodiments of the present disclosure illustrated in the accompanying drawings, it is not limited thereto. It will be apparent to those skilled in the art that various substitutions, modifications and changes may be made thereto without departing from the scope and spirit of the disclosure.

1-17. (canceled)

18. A system comprising:
a dual bit line data storage sub-system; and
a device configured to sense data in said dual bit line data storage sub-system, said device comprising
a pull-down circuit configured to discharge both bit lines of a selected data storage cell,
a pull-up circuit coupled to both bit lines and configured to compensate for the discharge of one of the bit lines that is at a voltage threshold corresponding to a first logic state, and
a sensing circuit coupled to both the bit lines and configured to sense the dual bit lines in the selected data storage cell.

19. The system according to claim 18, wherein said pull-down circuit comprises:
a first controlled switch coupled between a first bit line of the bit lines and a common node and having a control terminal coupled to a second bit line of the bit lines; and
a second controlled switch coupled between the second bit line and the common node and having a control terminal coupled to the first bit line.

20. The system according to claim 18, wherein said pull-up circuit comprises:
a fourth controlled switch coupled between a supply voltage and a first bit line of the bit lines and having a control terminal coupled to a second bit line of the bit lines; and
a fifth controlled switch coupled between the supply voltage and the second bit line and having a control terminal coupled to the first bit line.

21. The system according to claim 18, wherein said sensing circuit comprises:
a sixth controlled switch coupled between a common terminal and an output node and having a control terminal coupled to a first bit line of the bit lines; and
a seventh controlled switch coupled between a supply voltage and the output node and having a control terminal coupled to a second bit line of the bit lines.

22. A circuit configured to sense data in a dual bit line data storage sub-system comprising:
a pull-down circuit configured to discharge both bit lines of a selected data storage cell;
a pull-up circuit coupled to both bit lines and configured to compensate for the discharge of one of the bit lines that is at a voltage threshold corresponding to a first logic state; and
a sensing circuit coupled to both the bit lines and configured to sense the dual bit lines in the selected data storage cell.

23. The circuit according to claim 22, wherein said pull-down circuit comprises:
a first controlled switch coupled between a first bit line of the bit lines and a common node and having a control terminal coupled to a second bit line of the bit lines; and
a second controlled switch coupled between the second bit line and the common node and having a control terminal coupled to the first bit line.

24. The circuit according to claim 22, wherein said pull-up circuit comprises:
a fourth controlled switch coupled between a supply voltage and a first bit line of the bit lines and having a control terminal coupled to a second bit line of the bit lines; and
a fifth controlled switch coupled between the supply voltage and the second bit line and having a control terminal coupled to the first bit line.

25. The circuit according to claim 22, wherein said sensing circuit comprises:
a sixth controlled switch coupled between a common terminal and an output node and having a control terminal coupled to a first bit line of the bit lines; and
a seventh controlled switch coupled between a supply voltage and the output node and having a control terminal coupled to a second bit line of the bit lines.

26. A device configured to sense data in a dual bit line data storage sub-system, the device comprising:
a pull-down circuit configured to discharge both bit lines of a selected data storage cell;
a pull-up circuit coupled to both bit lines and configured to compensate for the discharge of one of the bit lines that is at a threshold voltage level; and
a sensing circuit coupled to both the bit lines and configured to sense the bit lines in the selected data storage cell;
said sensing circuit comprising an inverter configured to sense a voltage level when the one of the bit lines is at the threshold voltage level;
said pull-up circuit being configured to compensate for the discharge of one of the bit lines based upon the sensed voltage level from said sensing circuit.

27. The device according to claim 26, wherein said pull-down circuit comprises:
a first controlled switch coupled between a first bit line of the bit lines and a common node and having a control terminal coupled to a second bit line of the bit lines; and
a second controlled switch coupled between the second bit line and the common node and having a control terminal coupled to the first bit line.

28. The device according to claim 26, wherein said pull-up circuit comprises:
a fourth controlled switch coupled between a supply voltage and a first bit line of the bit lines and having a control terminal coupled to a second bit line of the bit lines; and
a fifth controlled switch coupled between the supply voltage and the second bit line and having a control terminal coupled to the first bit line.

29. The device according to claim 26, wherein said sensing circuit comprises:
a sixth controlled switch coupled between a common terminal and an output node and having a control terminal coupled to a first bit line of the bit lines; and
a seventh controlled switch coupled between a supply voltage and the output node and having a control terminal coupled to a second bit line of the bit lines.

30. A method for sensing data in a dual bit line data storage sub-system comprising:
discharging both bit lines of a selected data storage cell using a pull-down circuit;
compensating for the discharging of one of the bit lines that is at a voltage level corresponding to a first logic state using a pull-up circuit; and
sensing the discharging of a desired one of the bit lines using a sensing circuit.

31. The method according to claim 30, wherein sensing the discharging of a desired one of the bit lines using a sensing circuit comprises sensing the discharging of a desired one of the bit lines using an inverter sensing circuit.

32. The method according to claim 30, wherein the pull-down circuit comprises:
a first controlled switch coupled between a first bit line of the bit lines and a common node and having a control terminal coupled to a second bit line of the bit lines; and
a second controlled switch coupled between the second bit line and the common node and having a control terminal coupled to the first bit line.

33. The method according to claim 30, wherein the pull-up circuit comprises:
a fourth controlled switch coupled between a supply voltage and a first bit line of the bit lines and having a control terminal coupled to a second bit line of the bit lines; and
a fifth controlled switch coupled between the supply voltage and the second bit line and having a control terminal coupled to the first bit line.

34. The method according to claim 30, wherein the sensing circuit comprises:
a sixth controlled switch coupled between a common terminal and an output node and having a control terminal coupled to a first bit line of the bit lines; and
a seventh controlled switch coupled between a supply voltage and the output node and having a control terminal coupled to a second bit line of the bit lines.

35. A method of making a device configured to sense data in a dual bit line data storage sub-system, the method comprising:
configuring a pull-down circuit to discharge both bit lines of a selected data storage cell;
configuring a pull-up circuit to compensate for the discharge of one of the bit lines that is at a voltage threshold corresponding to a first logic state; and
configuring a sensing circuit to sense the dual bit lines in the selected data storage cell.

36. The method according to claim 35, wherein configuring the pull-down circuit comprises:
coupling a first controlled switch between a first bit line of the bit lines and a common node and coupling a control terminal of the first controlled switch to a second bit line of the bit lines; and
coupling a second controlled switch between the second bit line and the common node and coupling a control terminal of the second controlled switch to the first bit line.

37. The method according to claim 35, wherein configuring the pull-up circuit comprises:
coupling a fourth controlled switch between a supply voltage and a first bit line of the bit lines and coupling a control terminal of the fourth controlled switch to a second bit line of the bit lines; and
coupling a fifth controlled switch between the supply voltage and the second bit line and coupling a control terminal of the fifth controlled switch to the first bit line.

38. The method according to claim 35, wherein configuring the sensing circuit comprises:
coupling a sixth controlled switch between a common terminal and an output node and coupling a control terminal of the sixth controlled switch to a first bit line of the bit lines; and
coupling a seventh controlled switch between a supply voltage and the output node and coupling a control terminal of the seventh controlled switch to a second bit line of the bit lines.
